(19) United States
(12) Patent Application Publication
(10) Pub. No.: US 2015/0349295 A1
(43) Pub. Date: Dec. 3, 2015

(54) GAS PERMEATION MULTILAYER BARRIER WITH TUNABLE INDEX DECOUPLING LAYERS

(71) Applicant: SAMSUNG SDI CO., LTD., Yongin-Si (KR)

(72) Inventors: Damien Boesch, San Jose, CA (US); Lorenza Moro, Palo Alto, CA (US)

(21) Appl. No.: 14/723,371

(22) Filed: May 27, 2015

Related U.S. Application Data
(60) Provisional application No. 62/005,998, filed on May 30, 2014.

(51) Int. Cl. H01L 51/52

(52) U.S. Cl. CPC H01L 51/5256; H01L 2251/301; H01L 2251/5369

(57) ABSTRACT

Barrier stacks according to embodiments of the present invention achieve good optical properties by including a decoupling layer with a tunable refractive index. In some embodiments, the barrier stack includes one or more dyads, each of which includes a first layer comprising an organic-inorganic hybrid material, and a second layer comprising a barrier material. The first layer has a refractive index at an interface between the first layer and the second layer that is substantially matched to a refractive index of the second layer.

### CROSS-REFERENCE TO RELATED APPLICATION(S)

This application claims priority to and the benefit of U.S. Provisional Application Ser. No. 62/005,998, filed on May 30, 2014 and titled GAS PERMEATION MULTILAYER BARRIER WITH TUNABLE INDEX DECOUPLING LAYERS, the entire content of which is incorporated herein by reference.

### BACKGROUND

Many devices, such as organic light emitting devices and the like, are susceptible to degradation from the permeation of certain liquids and gases, such as water vapor and oxygen present in the environment, and other chemicals that may be used during the manufacture, handling or storage of the product. To reduce permeability to these damaging liquids, gases and chemicals, the devices are typically coated with a barrier coating or are encapsulated by incorporating a barrier stack adjacent one or both sides of the device.

Barrier coatings typically include a single layer of inorganic material, such as aluminum, silicon or aluminum oxides, or silicon nitrides. However, for many devices, such a single layer barrier coating does not sufficiently reduce or prevent oxygen or water vapor permeability. Indeed, in organic light emitting devices, for example, which require exceedingly low oxygen and water vapor transmission rates, these single layer barrier coatings do not adequately reduce or prevent the permeability of damaging gases, liquids and chemicals. Accordingly, in those devices (e.g., organic light emitting devices and the like), barrier stacks have been used in an effort to further reduce or prevent the permeation of damaging gases, liquids and chemicals.

In general, a barrier stack includes multiple dyads, each dyad being a two-layered structure including a barrier layer and a decoupling layer. The barrier stack can be deposited directly on the device to be protected, or may be deposited on a separate film or support, and then laminated onto the device. The decoupling layer serves to provide a planarized and/or smoothed surface for deposition of the barrier layer. As such, the decoupling layer is generally polymeric, and therefore has a refractive index significantly different than that of the inorganic barrier layer. This difference in refractive index between the decoupling layer and the barrier layer adversely affects the optical performance of the encapsulated device (e.g., an encapsulated OLED). For example, the refractive index differential between the two layers of the barrier stack results in Fresnel reflections and interference fringes in the transmittance spectra of the barrier stack.

### SUMMARY

According to some embodiments of the present invention, a barrier stack includes one or more dyads, where each dyad includes a first layer comprising an organic-inorganic hybrid material, and a second layer on the first layer and comprising a barrier material. The first layer comprising the organic-inorganic hybrid material has a refractive index that is tunable to a target value. In particular, the organic-inorganic hybrid material of the first layer includes either an organometallic polymer or inorganic nanoparticles dispersed in an organic polymeric matrix, and the concentration of the inorganic material (i.e., the concentration of metal atoms in the organometallic polymer or the concentration of inorganic nanoparticles dispersed in the polymer matrix) is sufficient to achieve a target refractive index of the layer. In some embodiments, for example, the first layer includes a sufficient concentration of the inorganic material to achieve a refractive index of the first layer that is substantially matched to the refractive index of the second layer (i.e., the barrier layer). As used herein, the term “substantially” is used as a term of approximation, and not as a term of degree, and is intended to account for the inherent deviation in the measurements and calculations used to determine the refractive index of the layer. For example, in some embodiments, a refractive index of the first layer is “substantially matched” to the refractive index of the second layer when the value of one of the two indices is 95% or greater than the value of the other of the two indices, e.g., 95% to 105% of the value of the other of the two indices. For example, in some embodiments, the value of one of the two indices may be 97% or greater than the value of the other of the two indices, e.g., 97% to 103% of the value of the other of the two indices. In some embodiments, for example, the refractive index of the first layer is “substantially matched” to the refractive index of the second layer when a difference in the refractive indices of the first layer and the second layer is 0.10 or less, for example, 0.05 or less.

The organic material of the organic-inorganic hybrid material of the first layer may be selected from organic polymers, inorganic polymers, organometallic polymers, hybrid organic/inorganic polymer systems, silicates, acrylate-containing polymers, alkylacrylate-containing polymers, methacrylate-containing polymers, silicone-based polymers, and combinations thereof.

The inorganic material of the organic-inorganic hybrid material of the first layer may be either bonded to the monomers in the polymer to form an organometallic polymer, or may be dispersed in a mixture of monomers as nanoparticles. The inorganic material may include metal atoms (e.g., that are bonded to the monomers to create an organometallic polymer), metal nanoparticles or metal oxide nanoparticles that may be dispersed in the monomers making up the polymer of the organic material. The inorganic material of the first layer may include any suitable metal atoms, metal nanoparticles or metal oxide nanoparticles. For example, the inorganic material of the first layer may include atoms, nanoparticles, or oxide nanoparticles of a transition metal or halogen. In some embodiments, for example, the inorganic material of the first layer may include atoms, nanoparticles, or oxide nanoparticles of Ti, Zr, Hf or Br. For example, in some embodiments, the inorganic material comprises nanoparticles of titania and/or zirconia. In some embodiments, the inorganic material includes a Hf or Zr atom as part of a monomer used to form the polymeric matrix. One or more different inorganic materials may also be used. For example, in some embodiments, the first layer may include both an organometallic polymer in which the monomers of the polymer are bonded to atoms of the inorganic material, as well as nanoparticles of a metal or oxide. In some embodiments, the first layer may include a mixture of different nanoparticles.

The barrier material of the second layer may be selected from metals, metal oxides, metal nitrides, metal oxynitrides, metal carbides, metal oxyborides, Al, Zr, Zn, Sn, Ti, and combinations thereof. For example, in some embodiments, the barrier material may include a metal oxide. In some embodiments, for example, the barrier material may include aluminum oxide and/or silicon oxide.

In some embodiments, a method of making a barrier stack includes forming one or more dyads, where forming each of the dyads includes forming a second layer comprising a barrier material over a first layer comprising the organic-inorganic material. The method further includes tuning the refractive index of the first layer to a target refractive index, for example, a refractive index that substantially matches the refractive index of the second layer. Tuning the refractive index of the first layer includes adjusting the concentration of the inorganic material in the organic-inorganic hybrid material of the first layer. Additionally, in embodiments in which the refractive index of the first layer is tuned to substantially match the refractive index of the second layer, the refractive index of the first layer is tuned to a value that is 95% or greater than the value of the refractive index of the second layer, e.g., 95% to 105% of the value of the refractive index of the second layer. For example, in some embodiments, the refractive index of the first layer may be tuned to a value that is 97% or greater than the value of the refractive index of the second layer, e.g., 97% to 103% of the value of the refractive index of the second layer. In some embodiments, for example, the refractive index of the first layer is tuned such that a difference in the refractive indices of the first layer and the second layer is 0.10 or less, for example, 0.05 or less.

### BRIEF DESCRIPTION OF THE DRAWINGS

The patent or application file contains at least one drawing executed in color. Copies of this patent or patent application publication with color drawing(s) will be provided by the office upon request and payment of the necessary fee.

These and other features and advantages of the present invention will be better understood by reference to the following detailed description when considered in conjunction with the following drawings, in which:

FIG. 1 is a schematic view of a barrier stack according to an embodiment of the present invention;

FIG. 2 is a schematic view of a barrier stack according to another embodiment of the present invention;

FIG. 3 is a schematic view of a barrier stack according to yet another embodiment of the present invention;

FIG. 4 is a graph comparing the optical transmittance spectra of the barrier structures of Example 1 (shown in green and denoted “T High RI”) and Comparative Example 1 (shown in red and denoted “T Std”) and a bare polyethylene naphthalate substrate (shown in blue and denoted “T Bare PEN”);

FIG. 5 is a graph comparing the difference in transmittance from the bare substrate of the barrier structures of Example 1 (shown in red and denoted “D High RI”) and Comparative Example 1 (shown in blue and denoted “D Std”); and

FIG. 6 is a graph comparing the fast Fourier Transform spectra of the barrier stacks of Example 1 (shown in red and denoted “FFT High RI”) and Comparative Example 1 (shown in blue and denoted “FFT Std”).

### DETAILED DESCRIPTION

In embodiments of the present invention, a barrier stack includes a decoupling layer including an organic-inorganic hybrid material. The inorganic component of the decoupling layer enables tuning of the refractive index of the decoupling layer, which in turn, enables improvements in the optical properties of the barrier stack. For example, in some embodiments, by appropriately adjusting the concentration of the inorganic component in the decoupling layer, the refractive index of the decoupling layer can be tuned to a target value. In some embodiments, for example, the refractive index of the decoupling is tuned to substantially match the refractive index of the barrier layer. Barrier stacks in which the decoupling layer and barrier layer have refractive indices that are substantially matched exhibit improved optical properties. For example, these barrier stacks exhibit reduced Fresnel reflections and interference fringes.

In some embodiments of the present invention, a barrier stack includes at least one dyad, each of which includes a first layer that acts as a smoothing or planarization layer, and a second layer that acts as a barrier layer. The layers of the barrier stack can be directly deposited on a device to be encapsulated (or protected) by the barrier stack, or may be deposited on a separate substrate or support, and then laminated on the device. The first layer of the dyad includes an organic-inorganic hybrid material that includes an organic component and an inorganic component. The first layer serves as a planarization, decoupling and/or smoothing layer. Specifically, the first layer decreases surface roughness, and encapsulates surface defects, such as pits, scratches, digs and particles, thereby creating a planarized surface that is ideal for the subsequent deposition of additional layers (e.g., the barrier layer). As used herein, the terms “first layer,” “smoothing layer,” “decoupling layer,” and “planarization layer” are used interchangeably, and all terms refer to the first layer, as now defined. The first layer can be deposited directly on the device to be encapsulated (e.g., an organic light emitting device), or may be deposited on a separate support. The first layer may be deposited on the device or substrate by any suitable deposition technique, some nonlimiting examples of which include vacuum processes and atmospheric processes. Some nonlimiting examples of suitable vacuum processes for deposition of the first layer include flash evaporation with in situ polymerization under vacuum, and plasma deposition and polymerization. Some nonlimiting examples of suitable atmospheric processes for deposition of the first layer include spin coating, ink jet printing, screen printing and spraying.

The organic-inorganic hybrid material of the first layer can include any suitable material capable of acting as a planarization, decoupling and/or smoothing layer. Some nonlimiting examples of suitable such materials include organic polymers, inorganic polymers, organometallic polymers, hybrid organic/inorganic polymer systems, and silicates. For example, in some embodiments, the organic-inorganic hybrid material may include an inorganic polymer, organometallic polymer, hybrid organic/inorganic polymer system, and/or a silicate, which include integrated (i.e., reacted and/or bonded) organic and inorganic components. In some embodiments, for example, the organic-inorganic hybrid material may include an acrylate-containing polymer, an alkylacrylate-containing polymer (including but not limited to methacrylate-containing polymers), or a silicon-based polymer bonded or reacted with an inorganic atom (i.e., the inorganic atom is part of the polymer's chemical structure). These polymers having integrated organic and inorganic components are referred to herein as “organic-inorganic hybrid polymer systems,” “organometallic polymers,” or like terms.

In some embodiments, however, the organic-inorganic hybrid material may include organic and inorganic components that are not necessarily integrated (i.e., reacted and/or otherwise bonded). For example, in some embodiments, the organic-inorganic hybrid material of the first layer may include an organic component, such as, e.g., an organic polymer matrix, and an inorganic component, such as, e.g., inorganic nanoparticles dispersed in the polymer matrix. In some embodiments, for example, the organic component may include an acrylate-containing polymer, an alkylacrylate-containing polymer (including but not limited to methacrylate-containing polymers), or a silicon-based polymer. These materials having mixed, but not necessarily integrated, organic and inorganic components, are referred to herein as “organic-inorganic hybrid dispersions,” “organic-inorganic hybrid suspensions,” or like terms.

The first layer comprising the organic-inorganic hybrid material has a refractive index that is tunable to a target value. In particular, the organic-inorganic hybrid material of the first layer includes either an organometallic polymer (i.e., an organic-inorganic hybrid material having integrated organic and inorganic components) or an inorganic component (e.g., inorganic nanoparticles) dispersed in the organic component (e.g., an organic polymeric matrix). The concentration of the inorganic component (i.e., either the concentration of metal atoms bonded to or reacted into the structure of the organometallic polymer, or the concentration of the inorganic components dispersed in the organic component) is sufficient to achieve a target refractive index. In some embodiments, for example, the first layer includes a sufficient concentration of the inorganic material to achieve a refractive index of the first layer that is substantially matched to the refractive index of the second layer (i.e., the barrier layer). As used herein, the term “substantially” is used as a term of approximation, and not as a term of degree, and as used in connection with this property is intended to account for the inherent deviation in the measurements and calculations used to determine the refractive index of the layer. For example, in some embodiments, a refractive index of the first layer is “substantially matched” to the refractive index of the second layer when the value of one of the two indices is 95% or greater than the value of the other of the two indices, e.g., 95% to 105% of the value of the other of the two indices. For example, in some embodiments, the value of one of the two indices may be 97% or greater than the value of the other of the two indices, e.g., 97%to 103% of the value of the other of the two indices. In some embodiments, for example, the refractive index of the first layer is “substantially matched” to the refractive index of the second layer when a difference in the refractive indices of the first layer and the second layer is 0.10 or less, for example, 0.05 or less.

The inorganic component (also referred to herein as the inorganic material) of the organic-inorganic hybrid material of the first layer may be either bonded to (or reacted into) the structure of the organic component to form an organometallic polymer (i.e., an organic-inorganic hybrid material having integrated organic and inorganic components), or may be dispersed in the organic component (e.g., a polymer matrix). The inorganic component may include metal atoms (e.g., that are bonded to or reacted into the chemical structure of the organic component to create an organometallic polymer), or may include metal nanoparticles or metal oxide nanoparticles that may be dispersed in the organic component (e.g., an organic polymer matrix). The inorganic material of the first layer may include any suitable inorganic material, e.g., metal atoms, metal nanoparticles or metal oxide nanoparticles. For example, the inorganic material of the first layer may include atoms, nanoparticles, or oxide nanoparticles of any suitable transition metal or halogen. In some embodiments, for example, the inorganic material of the first layer may include atoms, nanoparticles, or oxide nanoparticles of Ti, Zr, Hf or Br. In some embodiments, for example, the inorganic material includes nanoparticles or oxide nanoparticles of Ti, Zr, Hf and/or Br. For example, in some embodiments, the inorganic material includes nanoparticles of titania and/or zirconia. One or more different inorganic materials may also be used. For example, in some embodiments, the first layer may include both an organometallic polymer having integrated organic and inorganic components, as well as nanoparticles of a metal or metal oxide. Additionally, in some embodiments, the first layer may include a mixture of differently constituted nanoparticles (e.g., nanoparticles of different metals and/or different metal oxides).

In some embodiments in which the organic-inorganic material of the first layer includes an organic-inorganic hybrid material having integrated organic and inorganic components (e.g., an organometallic polymer), the hybrid material may be formed from one or more monomers including an inorganic atom. For example, in some embodiments, the hybrid material may include a monomer having an integrated metal atom, halogen atom or other heteroatom (e.g., N or S). For example, in some embodiments, the monomer may include an integrated Hf, Zr, Br, F, Cl, S and/or N atom. In some embodiments, for example, the monomer with an integrated inorganic atom may have a heteroaromatic or heterocyclic structure. Some nonlimiting examples of suitable monomers having an integrated heteroatom (or inorganic atom) include zirconium acrylate, zirconium carboxyethyl acrylate, hafnium carboxyethyl acrylate, zirconium bromonorbornanelactone carboxylate triacrylate, poly(pentabromophenyl methacrylate), poly(pentabromophenylacrylate), poly(pentabromobenzylmethacrylate), poly(pentabromobenzylacrylate), poly(2,4,6-tribromophenylmethacrylate), poly(vinylphenylsulfide), poly(1-naphthylmethacrylate), poly(2-vinylthiophene), poly(2,6-dichlorostyrene), poly(N-vinylphthalamide), poly(2-chlorostyrene), poly(pentachlorophenylmethacrylate), poly(1,1,1,3,3,3-hexafluoroisopropyl acrylate), poly(2,2,3,3,4,4,4-heptafluorobutylacrylate), poly(2,2,3,3,4,4,4-heptafluorobutylmethacrylate), poly(2,2,3,3,3-pentafluoropropylacrylate), poly(1,1,1,3,3,3-hexafluoroisopropylmethacrylate), poly(2,2,3,4,4,4-hexafluorobutylacrylate), poly(2,2,3,4,4,4-hexafluorobutylmethacrylate), poly(2,2,3,3,3-pentafluoropropyl methacrylate), poly(2,2,2-trifluoroethylacrylate), poly(2,2,3,3-tetrafluoropropylacrylate), poly(2,2,3,3-tetrafluoropropylmethacrylate), and poly(2,2,2-trifluoroethylmethacrylate.

In some embodiments, for example, higher refractive index monomers may be used to increase the refractive index of the resulting decoupling layer. Some nonlimiting examples of suitable higher refractive index monomers (e.g., having a refractive index of about 1.6 to about 1.75) include zirconium acrylate, zirconium carboxyethyl acrylate, hafnium carboxyethyl acrylate, zirconium bromonorbornanelactone carboxylate triacrylate, poly(pentabromophenyl methacrylate), poly(pentabromophenylacrylate), poly(pentabromobenzylmethacrylate), poly(pentabromobenzylacrylate), poly(2,4,6-tribromophenylmethacrylate), poly(vinylphenylsulfide), poly(1-naphthylmethacrylate), poly(2-vinylthiophene), poly(2,6-dichlorostyrene), poly(N-vinylphthalamide), poly(2-chlorostyrene), poly(pentachlorophenylmethacrylate).

In some embodiments, lower refractive index monomers can be used to decrease the refractive index of the resulting decoupling layer. Additionally, in some embodiments, a mixture of higher refractive index monomers and lower refractive index monomers may be used in order to tune or tailor the refractive index of the resulting decoupling layer to a desired value. Some nonlimiting examples of suitable lower refractive index monomers (e.g., having a refractive index of about 1.35 to about 1.45) include fluorinated monomers, such as, for example, poly(1,1,1,3,3,3-hexafluoroisopropyl acrylate), poly(2,2,3,3,4,4,4-heptafluorobutylacrylate), poly(2,2,3,3,4,4,4-heptafluorobutylmethacrylate), poly(2,2,3,3,3-pentafluoropropylacrylate), poly(1,1,1,3,3,3-hexafluoroisopropylmethacrylate), poly(2,2,3,4,4,4-hexafluorobutylacrylate), poly(2,2,3,4,4,4-hexafluorobutylmethacrylate), poly(2,2,3,3,3-pentafluoropropyl methacrylate), poly(2,2,2-trifluoroethylacrylate), poly(2,2,3,3-tetrafluoropropylacrylate), poly(2,2,3,3-tetrafluoropropylmethacrylate), and poly(2,2,2-trifluoroethylmethacrylate.

The organometallic polymer (or organic-inorganic hybrid material having integrated organic and inorganic components) may include any number of monomers having an inorganic atom, and may include both these monomers and wholly organic monomers in the polymer backbone (or matrix). The organic monomers in such a system can be any suitable monomers for use in polymer decoupling layers. For example, in some embodiments, the polymers may include modified versions of those described in U.S. Pat. No. 8,643,200, the entire content of which is incorporated herein by reference. In particular, the polymer systems may be similar to those described in the U.S. Pat. No. 8,643,200, but modified with one or more of the organic-inorganic monomers described herein. For example, in some embodiments, the polymer decoupling layer may include the polymer described in the U.S. Pat. No. 8,643,200 including one or more of the monomers described herein.

According to some embodiments in which the organic-inorganic material of the first layer includes an organic-inorganic dispersion or suspension, the dispersion or suspension may include the inorganic component (e.g., metal or metal oxide nanoparticles) at any concentration suitable to achieve the target refractive index (e.g., a refractive index that is substantially matched to the refractive index of the second, barrier layer). For example, in some embodiments, the concentration of the nanoparticles in the first layer may be 30 wt % or less, for example 10 wt % or less. In some embodiments, for example, the concentration of the nanoparticles in the first layer may be 1 wt % to 30 wt %, or b 1 wt % to 10 wt %. For example, in some embodiments the concentration of the inorganic component in the first layer may be b 5 wt % or less, or 1 wt % to 5 wt %. Additionally, in some embodiments, the nanoparticles in the dispersion or suspension may have any suitable average particle size, which may also be selected such that the refractive index of the first layer achieves a target value (such as, for example, a value that is substantially matched to the refractive index of the second layer). For example, in some embodiments, the nanoparticles in the dispersion or suspension may have an average particle size of 200 nm or less, for example, less than 100 nm. In some embodiments, the nanoparticles have an average particle size of 1 nm to 200 nm, or 1 nm to 100 nm. In some embodiments, for example, the nanoparticles may have an average particle size of 1 nm to 70 nm, or 1 nm to 50 nm, or 1 nm to 20 nm.

Additionally, in some embodiments, the first layer may have a refractive index gradient, in which the refractive index of the layer near the second layer (or barrier layer) is different from the refractive index of the layer near the substrate or device being encapsulated. For example, in some embodiments, the refractive index of the first layer may increase towards the interface with first layer. In some embodiments, for example, the refractive index of the first layer at or near the interface with the second layer (or barrier layer) may be elevated, or substantially matched to the refractive index of the second layer, and may be lower near the substrate or device. This refractive index gradient may be accomplished by any suitable manner. For example, in some embodiments, the first layer may be deposited in two steps, where the first step includes depositing an organic polymer (e.g., without an inorganic component), and the second step includes depositing a layer of the organic-inorganic hybrid material described above. Additionally, in some embodiments, the first layer may include multiple layers with different refractive indices that increase from the substrate towards the second layer. To accomplish such a structure for the first layer, for example, in some embodiments, the first layer may include a primary layer closest to the substrate with no or a small amount of inorganic component, and secondary layers with increasing amounts inorganic component (i.e., more inorganic component than the primary layer) as the layers get closer to the second layer (or barrier layer). The number of secondary layers may vary as desired, and each secondary layer may include any of the organic-inorganic hybrid materials described above. In these embodiments, the.secondary layer closest to (or contacting) the second layer (i.e., the barrier layer) has the target refractive index (e.g., the refractive index substantially matched to the refractive index of the second layer). In this manner, the refractive index of the first layer is substantially matched to the refractive index of the second layer (i.e., the barrier layer) at the interface between the layers, thereby reducing Fresnel reflections and interference at the interface between the decoupling layer and the barrier layer.

The first layer can have any suitable thickness such that the layer has a substantially planar and/or smooth layer surface. As used herein, the term “substantially” is used as a term of approximation and not as a term of degree, and as used in connection with this property is intended to account for normal variations and deviations in the measurement or assessment of the planar or smooth characteristic of the first layer. In some embodiments, for example, the first layer has a thickness of about 100 to 1000 nm, for example about 200 to 800 nm, or about 300 to 700 nm. In some embodiments, for example, the first layer has a thickness of about 500 nm to about 650 nm.

The second layer of the dyad is the layer that operates as the barrier layer, preventing the permeation of damaging gases, liquids and chemicals to the encapsulated device. Indeed, as used herein, the terms “second layer” and “barrier layer” are used interchangeably. The second layer is deposited on the first layer, and deposition of the second layer may vary depending on the material used for the second layer. However, in general, any deposition technique and any deposition conditions can be used to deposit the second layer. For example, the second layer may be deposited using a vacuum process, such as sputtering, chemical vapor deposition, metalorganic chemical vapor deposition, plasma enhanced chemical vapor deposition, evaporation, sublimation, electron cyclotron resonance-plasma enhanced chemical vapor deposition, and combinations thereof.

In some embodiments, however, the second layer is deposited by AC or DC sputtering. For example, in some embodiments, the second layer is deposited by AC sputtering. The AC sputtering deposition technique offers the advantages of faster deposition, better layer properties, process stability, control, fewer particles and fewer arcs. The conditions of the AC sputtering deposition are not particularly limited, and as would be understood by those of ordinary skill in the art, the conditions will vary depending on the area of the target and the distance between the target and the substrate. In some exemplary embodiments, however, the AC sputtering conditions may include a power of about 3 to about 6 kW, for example about 4 kW, a pressure of about 2 to about 6 mTorr, for example about 4.4 mTorr, an Ar flow rate of about 80 to about 120 sccm, for example about 100 sccm, a target voltage of about 350 to about 550 V, for example about 480V, and a track speed of about 90 to about 200 cm.min, for example about 141 cm/min. Also, although the inert gas used in the AC sputtering process can be any suitable inert gas (such as helium, xenon, krypton, etc.), in some embodiments, the inert gas is argon (Ar).

The material of the second layer is not particularly limited, and may be any material suitable for substantially preventing or reducing the permeation of damaging gases, liquids and chemicals (e.g., oxygen and water vapor) to the encapsulated device. Some nonlimiting examples of suitable materials for the second layer include metals, metal oxides, metal nitrides, metal oxynitrides, metal carbides, metal oxyborides, and combinations thereof. Those of ordinary skill in the art would be capable of selecting a suitable metal for use in the oxides, nitrides and oxynitrides based on the desired properties of the layer. However, in some embodiments, for example, the metal may be Al, Zr, Si, Zn, Sn or Ti.

The density and refractive index of the second layer is not particularly limited and will vary depending on the material of the layer. However, in some exemplary embodiments, the second layer may have a refractive index of about 1.6 or greater, e.g., 1.675. The thickness of the second layer is also not particularly limited. However, in some exemplary embodiments, the thickness is about 20 nm to about 100 nm, for example about 40 nm to about 70 nm. In some embodiments, for example, the thickness of the third layer is about 40 nm. As is known to those of ordinary skill in the art, thickness is dependent on density, and density is related to refractive index. See, e.g., Smith, et al., “Void formation during film growth: A molecular dynamics simulation study,” J. Appl. Phys., 79 (3), pgs. 1448-1457 (1996); Fabes, et al., “Porosity and composition effects in sol-gel derived interference filters,” Thin Solid Films, 254 (1995), pgs. 175-180; Jerman, et al., “Refractive index of this films of SiO₂, ZrO₂, and HfO₂ as a function of the films' mass density,” Applied Optics, vol. 44, no. 15, pgs. 3006-3012 (2005); Mergel, et al., “Density and refractive index of TiO₂ films prepared by reactive evaporation,” Thin Solid Films, 3171 (2000) 218-224; and Mergel, D., “Modeling TiO₂ films of various densities as an effective optical medium,” Thin Solid Films, 397 (2001) 216-222, all of which are incorporated herein by reference. Also, the correlation between film density and barrier properties is described, e.g., in Yamada, et al., “The Properties of a New Transparent and Colorless Barrier Film,” Society of Vacuum Coaters, 505/856-7188, 38^{th} Annual Technical Conference Proceedings (1995) ISSN 0737-5921, the entire content of which is also incorporated herein by reference. Accordingly, those of ordinary skill in the art would be able to calculate the density of the second layer based on the refractive index and/or thickness information.

In the production of ultra-barriers, defects are introduced in the inorganic barrier layer (i.e., the second layer of the dyad) by the vacuum deposition process and the handling of the films. These defects are mainly created by particles falling on the substrate before and during the deposition process, as well as scratches and indentations created by handling (e.g., contact with rolls in web systems). The extrinsic defects created in the barrier layer during the production process are ingress paths for moisture and oxygen. These defects render the highly impermeable dense inorganic barrier layer (i.e., the second layer of the dyad) less effective as a permeation barrier against moisture and oxygen. The standard approach to minimize the impact of these defects is the use of multilayer barrier structures including a stack of several dyads. One of the functions of the organic layer (i.e., the first layer in the dyad) in such structures is to cover the particles on the substrate and landing on it during the barrier fabrication. Another function of the organic polymer layer (i.e., the first layer of the dyad) is to provide a smooth surface for the deposition of a high quality inorganic barrier layer (i.e., the second layer of the dyad). However, conventional organic smoothing or planarization layers have lower refractive indices than the barrier layers of the stacks. As a result of this mismatch in refractive index between the layers of the multilayer stack, the stack as a whole can exhibit increased Fresnel reflections and interference fringes, which adversely impact the optical performance of the stack. However, according to embodiments of the present invention, the organic layer of the multilayer stack includes an organic-inorganic hybrid material that can be tuned to a target refractive index by adjusting the concentration of the inorganic component. As a result, the layers of the multilayer stack can have refractive indices that are substantially matched, thereby reducing the Fresnel reflections and interference fringes, and improving the optical quality and performance of the barrier stack.

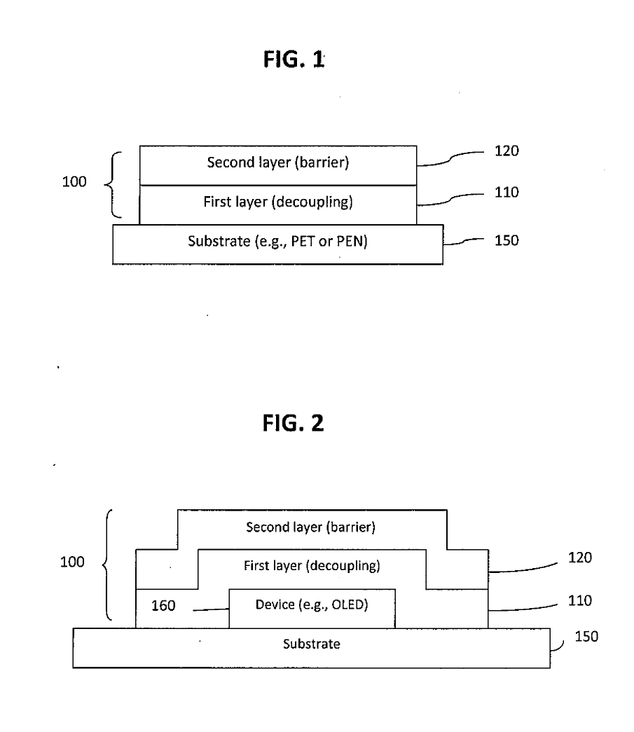

Exemplary embodiments of a barrier stack according to the present invention are illustrated in FIGS. 1 and 2. The barrier stack 100 depicted in FIG. 1 includes a first layer 110 which includes a decoupling layer or smoothing layer (i.e., the first layer discussed above), and a second layer 120 which includes a barrier layer (i.e., the second layer discussed above). In FIG. 1, the barrier stack 100 is deposited on a substrate 150, for example any common substrate, nonlimiting examples of which may include polyethylene terephthalate (PET), polyethylene naphthalate (PEN), polycarbonate, polyimide, and polyetherether ketone (PEEK). In some embodiments, for example, the substrate can be selected based on its refractive index. For example, in some embodiments, the material of the substrate may be selected such that the refractive index is close to the refractive index of the first and/or second layer. In some embodiments, for example, the substrate may include a polyethylene naphthalate having an elevated refractive index, e.g., a refractive index of about 1.7. One nonlimiting example of such a substrate material is the polyethylene naphthalate material, TEONEX®, available from Teijin DuPont Films (Japan). In FIG. 2, the barrier stack 100 is deposited directly on the device 160, e.g., an organic light emitting device.

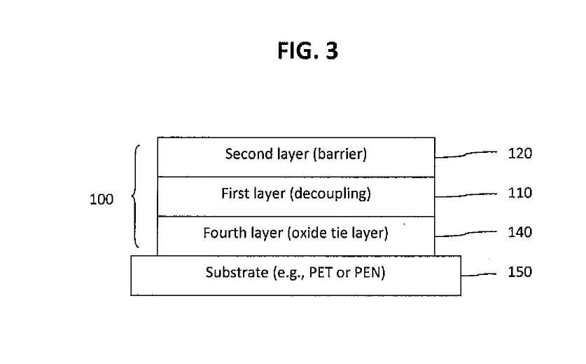

In addition to the first and second layers 110 and 120, respectively, making up a dyad, some exemplary embodiments of the barrier stack 100 can include a fourth layer 140 between the first layer 110 and the substrate 150 or the device 160 to be encapsulated. Although the inventive barrier stacks are discussed herein and depicted in the accompanying drawings as including first and second layers 110 and 120, respectively, of a dyad, and a fourth layer 140, it is understood that these layers may be deposited on the substrate 150 or the device 160 in any order, and the identification of the first, second and fourth layers as first, second, and fourth, respectively, does not mean that these layers must be deposited in that order. Indeed, as discussed here, and depicted in FIG. 3, in some embodiments, the fourth layer 140 is deposited on the substrate 150 or device 140 prior to deposition of the first layer 110.

The fourth layer 140 acts as a tie layer, improving adhesion between the layers of the barrier stack 100 and the substrate 150 or the device 160 to be encapsulated. The material of the fourth layer 140 is not particularly limited, and can include the materials described above with respect to the second layer. Also, the material of the fourth layer may be the same as or different from the material of the second layer. The materials of the second layer are described in detail above.

Additionally, the fourth layer may be deposited on the substrate or the device to be encapsulated by any suitable technique, including, but not limited to the techniques described above with respect to the second layer. In some embodiments, for example, the fourth layer may be deposited by AC or DC sputtering under conditions similar to those described above for the second layer. Also, the thickness of the deposited fourth layer is not particularly limited, and can be any thickness suitable to effect good adhesion between the first layer of the barrier stack and the substrate or device to be encapsulated. In some embodiments, for example, the fourth (tie) layer can have a thickness of about 20 nm to about 60 nm, for example, about 40 nm.

An exemplary embodiment of a barrier stack 100 according to the present invention including a fourth layer 140 is depicted in FIG. 3. The barrier stack 100 depicted in FIG. 3 includes a first layer 110 which includes a decoupling layer (i.e., first layer discussed above), a fourth layer 140 which includes an oxide tie layer, and a second layer 120 which includes a barrier layer. In FIG. 3, the barrier stack 100 is deposited on a substrate 150, for example any common substrate, nonlimiting examples of which may include PET, PEN, polycarbonate, polyimide, and polyetherether ketone (PEEK). In some embodiments, for example, the substrate may include a polyethylene naphthalate having an elevated refractive index, e.g., a refractive index of about 1.7. One nonlimiting example of such a substrate material is the polyethylene naphthalate material, TEONEX®, available from Teij in DuPont Films (Japan), which has a refractive index of about 1.7. However, it is understood that the barrier stack 100 can alternatively be deposited directly on the device 160, e.g., an organic light emitting device, as depicted in FIG. 2 with respect to the embodiments not including the fourth layer.

In some embodiments of the present invention, a method of making a barrier stack includes providing a substrate 150, which may be a separate substrate support or may be a device 160 for encapsulation by the barrier stack 100 (e.g., an organic light emitting device or the like). The method further includes forming a first layer 110 on the substrate. The first layer 110 is as described above and acts as a decoupling/smoothing/planarization layer. As also discussed above, the first layer 110 may be deposited on the device 160 or substrate 150 by any suitable deposition technique, including, but not limited to, vacuum processes and atmospheric processes. Some nonlimiting examples of suitable vacuum processes for deposition of the first layer include flash evaporation with in situ polymerization under vacuum, and plasma deposition and polymerization. Some nonlimiting examples of suitable atmospheric processes for deposition of the first layer include spin coating, ink jet printing, screen printing, slot die coating and spraying. For example, in some embodiments in which the first layer includes an organometallic polymer (i.e., with integrated organic and inorganic components), the first layer may be deposited by a suitable vacuum process, such as, for example, flash evaporation. In some embodiments in which the first layer includes an organic-inorganic hybrid dispersion or suspension (e.g., a polymer matrix with dispersed or suspended nanoparticles), the first layer may be deposited by a suitable atmospheric process, e.g., spraying, slot die coating, bar coating, spin coating, or ink jet printing. Also, in embodiments in which the first layer includes an organic-inorganic hybrid dispersion or suspension, the method further includes dispersing or suspending the inorganic component (e.g., nanoparticles) in the organic component (e.g., a polymer matrix), and then depositing the dispersion or suspension on the substrate or device to be encapsulated.

The method further includes depositing a second layer 120 on the surface of the first layer 110. The second layer 120 is as described above and acts as the barrier layer of the barrier stack, serving to substantially prevent or substantially reduce the permeation of damaging gases, liquids and chemicals to the underlying device. The deposition of the second layer 120 may vary depending on the material used for the second layer. However, in general, any deposition technique and any deposition conditions can be used to deposit the second layer. For example, the second layer 120 may be deposited using a vacuum process, such as sputtering, chemical vapor deposition, metalorganic chemical vapor deposition, plasma enhanced chemical vapor deposition, evaporation, sublimation, electron cyclotron resonance-plasma enhanced chemical vapor deposition, and combinations thereof. In some embodiments, however, the second layer 120 is deposited by AC or DC sputtering, for example pulsed AC or pulsed DC sputtering. While any suitable conditions for deposition can be employed, some suitable conditions are described above.

In some embodiments, the method further includes depositing a fourth layer 140 between the substrate 150 (or the device 160 to be encapsulated) and the first layer 110. The fourth layer 140 is as described above and acts as a tie layer for improving adhesion between the substrate or device and the first layer 110 of the barrier stack 100. The fourth layer 140 may be deposited by any suitable technique, as discussed above. For example, as also discussed above, the fourth layer 140 may be deposited on the substrate 150 (or the device 160 to be encapsulated) by AC or DC sputtering, e.g., pulsed AC or pulsed DC sputtering.

The following Examples are provided for illustrative purposes only, and do not limit the present disclosure.

### EXAMPLE 1

A barrier stack was prepared by spin coating a monomer blend including an acrylate monomer chemically bonded to Zr atoms as a first layer on a polyethylene naphthalate substrate (TEONEX®, available from Teijin DuPont Films (Japan), having a refractive index of about 1.7). After spin coating, the sample was heated at 80 C for 1 minute, and then cured by UV radiation. The first layer had a thickness of about 500 nm, and a refractive index of about 1.61. A second layer including an aluminum oxide was deposited by sputtering on the first layer to a thickness of about 40 nm. The refractive index of the oxide layer was about 1.6 to about 1.7.

### COMPARATIVE EXAMPLE 1

A barrier stack was prepared as in Example 1, except that the material of the first layer was an acrylate polymer without an inorganic component that was deposited by flash evaporation. The first layer had a refractive index of about 1.47.

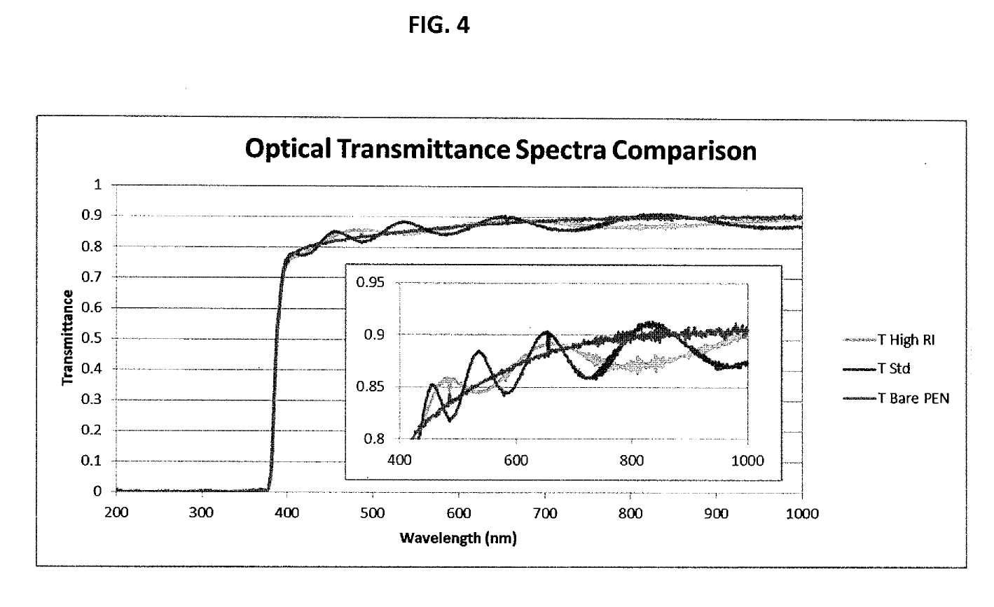

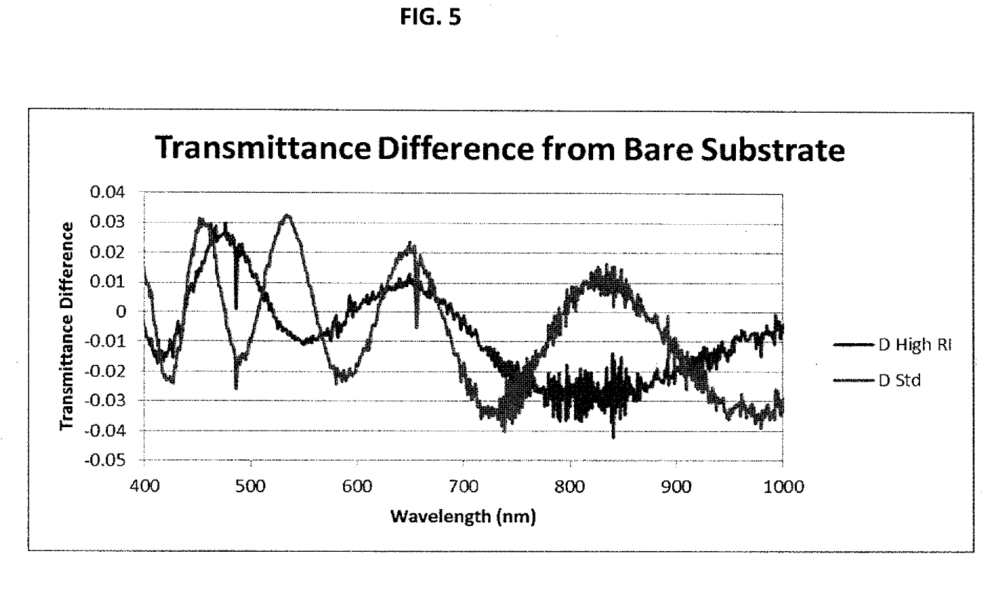

FIG. 4 is a graph comparing the optical transmittance of a bare polyethylene naphthalate substrate (shown in blue and denoted “T bare PEN”), the barrier stack according to Example 1 (shown in green and denoted “T High RI”), and the barrier stack according to Comparative Example 1 (shown in red and denoted “T Std”). As can be seen by comparing the data lines in FIG. 5 for Example 1 and Comparative Example 1 to the bare substrate, interference fringes are caused by Fresnel reflections at the interfaces of the layers in the barrier stack. However, FIG. 5 shows that the barrier stack according to Comparative Example 1 (including a standard polymer as the first (or decoupling) layer) showed more interference fringes than the barrier stack according to Example 1 (including a first layer with a higher refractive index that is substantially matched to the refractive index of the oxide layer). The inset in the figure is an exploded view of the 400 to 1000 nm region at 0.8 to 0.95 transmittance, providing a clearer image of the differences in the interference fringes.

Additionally, FIG. 5 is graph comparing the difference in transmittance from the bare substrate of the barrier stacks according to Example 1 (shown in red and denoted “D High RI”) and Comparative Example 1 (shown in blue and denoted “D Std”). In particular, FIG. 5 shows the difference between the spectrum of the barrier stacks and that of the bare substrate. As can be seen in FIG. 5, the barrier stack of Comparative Example 1 showed reduced spacing and higher peak-to-valley amplitudes for the interference fringes, indicating higher interference.

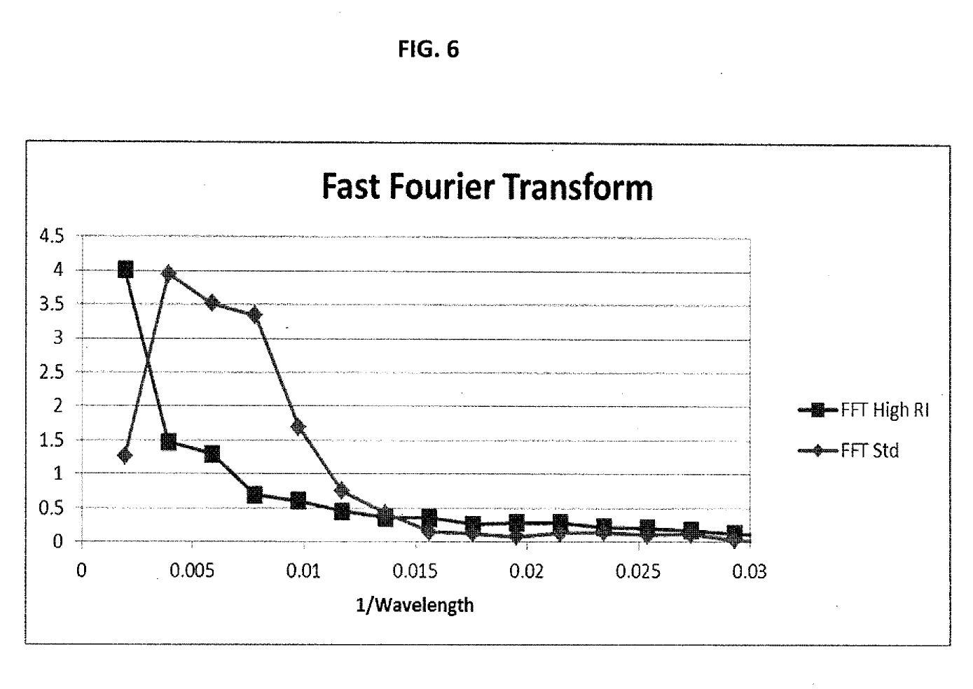

FIG. 6 is a graph comparing the fast Fourier transform spectra of the barrier stacks of Example 1 (shown in red and denoted “FFT High RI”) and Comparative Example 1 (shown in blue and denoted “FFT Std”). In particular, fast Fourier transform was performed to analyze the fringe spacing within the transmittance spectra. As can be seen in FIG. 6, the barrier stack according to Comparative Example 1 showed a broad peak corresponding to fringe spacing of 256 nm. In contrast, the barrier stack according to Example 1 has increased fringe spacing such that the peak in the Fourier transform plot is approaching infinite fringe spacing. Accordingly, FIG. 5 shows I0 increased fringe spacing for the barrier stack of Example 1, indicating significantly reduced interference compared to the barrier stack of Comparative Example 1.

As discussed above, barrier stacks according to embodiments of the present invention in which the first (smoothing or decoupling) layer includes an increased refractive index (such as, e.g., a refractive index substantially matched to the refractive index of the second (oxide or barrier) layer) register reduced Fresnel reflections at the interfaces between the first layer and the second layer. This reduction in Fresnel reflections leads to increased spacing and reduced amplitudes of the fringes in the transmittance spectra. As fringes cause constructive and destructive interference for different wavelengths, the reduced interference enables barrier films and stacks with improved optical performance, e.g., that do not impart color changes to the transmitted light. Additionally, because the barrier stacks according to embodiments of the present invention exhibit reduced Fresnel reflections at the interfaces between the first and second layers of the dyads of the stack, barrier stacks with multiple dyads will register even greater improvements due to the increased number of interfaces.

While certain exemplary embodiments of the present invention have been illustrated and described, it is understood by those of ordinary skill in the art that certain modifications and changes can be made to the described embodiments without departing from the spirit and scope of the present invention.

What is claimed is:

1. A barrier stack, comprising:
one or more dyads, each dyad comprising a first layer comprising an organic-inorganic hybrid material, and a second layer on the first layer and comprising a barrier material;
the first layer having a refractive index at an interface between the first layer and the second layer that is substantially matched to a refractive index of the second layer.

2. The barrier stack of claim I, further comprising a fourth layer, wherein the first layer is on the fourth layer.

3. The barrier stack of claim 1, wherein the organic-inorganic hybrid material comprises an organometallic polymer or a dispersion of an inorganic component in an organic component.

4. The barrier stack of claim 1, wherein the organic-inorganic hybrid material comprises inorganic nanoparticles dispersed in an organic matrix.

5. The barrier stack of claim 4, wherein the inorganic nanoparticles comprise nanoparticles of a metal or metal oxide.

6. The barrier stack of claim 4, wherein the inorganic nanoparticles comprise nanoparticles or oxide nanoparticles of Ti, Zr, Hf or Br.

7. The barrier stack of claim 1, wherein the refractive index of the first layer is 95% or greater than the refractive index of the second layer.

8. The barrier stack of claim 1, wherein a difference between the refractive index of the second layer and the refractive index of the first layer is 0.10 or less.

9. The barrier stack of claim 1, wherein the first layer comprises a refractive index gradient in which the refractive index of the first layer is greatest at the interface between the first layer and the second layer.

10. A method of making a barrier stack, comprising:
forming one or more dyads, wherein forming each of the dyads comprises forming a first layer comprising an organic-inorganic hybrid material, and forming a second layer comprising a barrier material over the first layer, the first layer having a refractive index at an interface with the second layer that is substantially matched to a refractive index of the second layer.

11. The method of claim 10, further comprising forming a fourth layer, wherein the first layer is formed on the fourth layer.

12. The method of claim 10, wherein the organic-inorganic hybrid material comprises an organometallic polymer or a dispersion of an inorganic component in an organic component.

13. The method of claim 10, wherein the organic-inorganic hybrid material comprises inorganic nanoparticles dispersed in an organic matrix.

14. The method of claim 13, wherein the inorganic nanoparticles comprise nanoparticles of a metal or metal oxide.

15. The method of claim 13, wherein the inorganic nanoparticles comprise nanoparticles or oxide nanoparticles of Ti, Zr, Hf or Br.

16. The method of claim 10, wherein the refractive index of the first layer is 95% or greater than the refractive index of the second layer.

17. The method of claim 10, wherein a difference between the refractive index of the second layer and the refractive index of the first layer is 0.10 or less.

18. The method of claim 10, wherein the first layer comprises a refractive index gradient in which the refractive index of the first layer is greatest at the interface between the first layer and the second layer.

19. The method of claim 18, wherein forming the first layer comprises forming a primary layer having a first refractive index, and forming a secondary layer having a second refractive index, the second refractive index being greater than the first refractive index and being at the interface of the first layer and the second layer.
